(19) United States
(12) Patent Application Publication
(10) Pub. No.: US 2005/0212074 A1
(43) Pub. Date: Sep. 29, 2005

(54) Semiconductor device and method of manufacturing the same

(75) Inventors: Kentaro Sera, Aizuwakamatsu (JP); Hiroyuki Nansei, Aizuwakamatsu (JP); Manabu Nakamura, Aizuwakamatsu (JP); Masahiko Higashi, Aizuwakamatsu (JP); Yukihiro Utsuno, Aizuwakamatsu (JP); Hideo Takagi, Aizuwakamatsu (JP); Tatsuya Kajita, Aizuwakamatsu (JP)

Correspondence Address: ARMSTRONG, KRATZ, QUINTOS, HANSON & BROOKS, LLP, 1725 K STREET, NW, SUITE 1000, WASHINGTON, DC, 20006, US

(73) Assignee: FUJITSU AMD SEMICONDUCTOR LIMITED, Fukushima (JP)

(21) Appl. No.: 11/065,307

(22) Filed: Feb. 25, 2005

Related U.S. Application Data
(63) Continuation of application No. PCT/JP03/08286, filed on Jun. 30, 2003.

(30) Foreign Application Priority Data
Aug. 30, 2002 (JP) 2002-255526

(51) Int. Cl. H01L 21/76; H01L 29/00

(52) U.S. Cl. 257/499

(57) ABSTRACT

A trench (4) is formed in a semiconductor substrate (1), and then a plasma oxynitride film (5) is formed on a side wall surface and a bottom surface of the trench (4) at a temperature of approximately 300° C. to 650° C. At such a temperature, no outward diffusion of impurities from the semiconductor substrate (1) occurs. Therefore, any problems such as formation of a parasitic transistor hardly occur even when ions of impurities are not implanted thereafter. After the plasma oxynitride film (5) is formed, it is thermally oxidized, and a portion where the outermost surface of the semiconductor substrate (1) meets the wall surface of the trench (4) is turned into a curved surface. As a result, the outermost surface of the semiconductor substrate (1) and the wall surface of the trench (4) meet each other while forming a curved surface, and hence a parasitic transistor is hardly formed at this portion. Consequently, formation of a hump is prevented, thereby achieving favorable characteristics.

### TECHNICAL FIELD

The present invention relates to a semiconductor device and a method of manufacturing the same, which employ a shallow trench isolation (STI) method for element isolation.

### BACKGROUND ART

One of element isolating techniques for isolating elements such as transistors from each other is an STI method. FIG. 13 to FIG. 17 are cross-sectional views showing, in order of steps, a conventional method of manufacturing a semiconductor device employing the STI method as an element isolating method. Note that views A and views B in FIG. 13 to FIG. 17 show cross sections which are orthogonal to each other. In other words, a cross section taken along the II-II line in each view A in FIG. 13 to FIG. 17 corresponds to each view B.

In the conventional method of manufacturing a semiconductor device, first, as shown in FIG. 13A and FIG. 13B, an oxide film 52 is formed on the surface of a silicon substrate 51, and a SiN film 53 is formed thereon. In the silicon substrate 51, an impurity such as boron is introduced. Next, a resist film is formed on the SiN film 53, and this resist film is patterned in a shape having openings at portions where element isolation regions are to be formed, thereby forming a resist pattern 61. Incidentally, when boron is introduced in the silicon substrate 51, the silicon substrate 51 becomes a p-type semiconductor substrate, but there may be a case that an n-type impurity is introduced in the silicon substrate 51 in advance so that the silicon substrate 51 becomes an n-type semiconductor substrate.

Next, as shown in FIG. 14A and FIG. 14B, with the resist pattern 61 being a mask, the SiN film 53, the oxide film 52, and the silicon substrate 51 are etched. As a result, trenches 54 are formed in the silicon substrate 51. Then, the resist pattern 61 is removed.

Thereafter, as shown in FIG. 15A and FIG. 15B, the silicon substrate 51 is thermally oxidized at a temperature of approximately 900° C. to 1100° C. to thereby form thermally oxidized films 55 on side wall surfaces and on bottom surfaces of the trenches 54.

Subsequently, as shown in FIG. 16A and FIG. 16B, a silicon oxide film 56 is formed on the entire surface by a CVD method.

Next, a planarization etching of the silicon oxide film 56 is performed until the SiN films 53 are exposed by a CMP method. Then, the SiN films 53 remaining on regions other than the regions where the element isolation regions are to be formed are removed. By these steps, element isolation regions 57 are formed as shown in FIG. 17A and FIG. 17B.

However, in the manufacturing method as described above, when the thermally oxidized films 55 are formed on the side wall surfaces and the bottom surfaces of the trenches 54, a thermal processing at a high temperature causes outward diffusion of impurities, boron for example, introduced in the silicon substrate 51 as shown in FIG. 18. Especially, during this thermal oxidization, since the SiN films 53 are formed on the regions other than the regions where the element isolation regions are to be formed, the outward diffusion of impurities easily occurs in the vicinity of each wall surface of the trenches 54 formed in the silicon substrate 51. As a result, in the vicinity of each wall surface, there is formed a region 58 in which an impurity concentration becomes low and uneven.

When such a region 58 in which the concentration is uneven exists, a parasitic transistor is formed on an upper end corner of each wall surface, which changes characteristics of the thermally oxidized films 55. Accordingly, there arises a problem such that it becomes necessary to implant ions of impurities such as boron again into the vicinity of the region 58 in order to eliminate the region 58.

Then, in order to prevent the outward diffusion of impurities, there is proposed a method of forming an oxide film on side wall surfaces and bottom surfaces of trenches by performing plasma oxidization instead of the thermal oxidization. FIG. 19A and FIG. 19B are cross-sectional views showing a conventional method of manufacturing a semiconductor device employing the plasma oxidization. A cross section taken along the III-III line in FIG. 19A corresponds to FIG. 19B. Note that in FIG. 19A and FIG. 19B, the same reference numeral are designated to the same components as those shown in FIG. 13A and FIG. 13B and FIG. 17A and FIG. 17B. According to this conventional manufacturing method, plasma oxide films 59 are formed on the side wall surfaces and the bottom surfaces of the trenches 54.

In the plasma oxidization employed in this method, a high temperature processing as high as the thermal oxidization is not necessary. For example, film formation is carried out at a temperature of approximately 400° C. Thus, the outward diffusion of impurities such as boron is prevented.

However, in the conventional method of manufacturing a semiconductor device employing the plasma oxidization, although the outward diffusion of impurities is suppressed, there arises a problem such as formation of a parasitic transistor. Such a phenomenon is sometimes called a hump.

The present invention is made in view of such problems, and an object thereof is to provide a semiconductor device and a method of manufacturing the same capable of preventing formation of a hump and achieving favorable characteristics.

### SUMMARY OF THE INVENTION

As a result of earnest studies to solve the above-described problems, the present inventors have found that the conventional method of manufacturing a semiconductor device employing the plasma oxidization result in that, as shown in FIG. 20, an upper end corner portion of each wall surface of the trenches 54 formed in the silicon substrate 51 remains sharp and thereby forms a hump. Further, the present inventors have also found that the reason why the corner portion remains sharp is such that the corner portion is not rounded in the plasma oxidization because the plasma oxide film 59 is formed at a low temperature, whereas the corner portion is rounded in the thermal oxidization due to a high temperature processing. Consequently, in order to eliminate such a cause, the present inventors have devised various aspects of the invention described below.

A method of manufacturing a semiconductor device according to the present invention is characterized in that it forms a trench for element isolation in a surface of a semiconductor substrate, forms an insulation film thereafter at least on a side wall surface of the trench by a sequence of film forming methods including a plasma oxidizing method and a plasma nitriding method or at least one of the plasma oxidizing method and the plasma nitriding method, and subsequently, thermally oxidizes the semiconductor substrate to thereby turn a topmost portion of the side wall surface of the trench of the semiconductor substrate into a gently curved surface.

The semiconductor device according to the present invention manufactured by such a method has: a semiconductor substrate having a surface in which a trench for element isolation is formed; one kind of insulation film selected from the group consisting of a plasma oxide film, a plasma nitride film, and a plasma oxynitride film and is formed at least on a side wall surface of the trench; and an insulation film for element isolation, the insulation film being embedded in the trench. This semiconductor device is characterized in that a topmost portion of the side wall surface of the trench of the semiconductor substrate is formed in a gently curved surface.

The above-described method of manufacturing the semiconductor device according to the present invention forms the plasma oxide film, the plasma oxynitride film, or the plasma nitride film at least on the side wall surface of the trench, so that the outward diffusion of impurities from the semiconductor substrate does not occur when this insulation film is formed. Further, when merely the plasma oxide film, the plasma oxynitride film, or the plasma nitride film is formed, reliability becomes low due to formation of a parasitic transistor, similarly to the conventional method of forming a plasma oxide film. On the contrary, in the present invention, the plasma oxide film, the plasma oxynitride film or the plasma nitride film is formed, and then this insulation film is oxidized to thereby turn the portion where the outermost surface of the semiconductor substrate meets the wall surface of the trench into a curved surface. As a result, the outermost surface of the semiconductor substrate and the wall surface of the trench meet each other while forming a curved surface, and hence a parasitic transistor is hardly formed at this portion. Therefore, a semiconductor device having favorable characteristics and high reliability can be easily obtained.

### BRIEF DESCRIPTION OF THE DRAWINGS

FIG. 1A and FIG. 1B are cross-sectional views showing a method of manufacturing a semiconductor device according to an embodiment of the present invention;

FIG. 2A and FIG. 2B are views showing the method of manufacturing the semiconductor device according to the embodiment of the present invention, which are cross-sectional views showing steps subsequent to those shown in FIG. 1A and FIG. 1B;

FIG. 3A and FIG. 3B are views showing the method of manufacturing the semiconductor device according to the embodiment of the present invention, which are cross-sectional views showing steps subsequent to those shown in FIG. 2A and FIG. 2B;

FIG. 4A and FIG. 4B are views showing the method of manufacturing the semiconductor device according to the embodiment of the present invention, which are cross-sectional views showing steps subsequent to those shown in FIG. 3A and FIG. 3B;

FIG. 5A and FIG. 5B are views showing the method of manufacturing the semiconductor device according to the embodiment of the present invention, which are cross-sectional views showing steps subsequent to those shown in FIG. 4A and FIG. 4B;

FIG. 6A and FIG. 6B are views showing the method of manufacturing the semiconductor device according to the embodiment of the present invention, which are cross-sectional views showing steps subsequent to those shown in FIG. 5A and FIG. 5B;

FIG. 7 is a cross-sectional view showing a state of the semiconductor substrate according to the embodiment of the present invention;

FIG. 8A and FIG. 8B are views showing a case of forming a plasma nitride film in the method of manufacturing the semiconductor device according to the embodiment of the present invention, which are cross-sectional views corresponding to the steps shown in FIG. 3A and FIG. 3B;

FIG. 9A and FIG. 9B are views showing the case of forming the plasma nitride film in the method of manufacturing the semiconductor device according to the embodiment of the present invention, which are cross-sectional views corresponding to the steps shown in FIG. 4A and FIG. 4B;

FIG. 10A and FIG. 10B are views showing a case of forming a plasma oxide film in the method of manufacturing the semiconductor device according to the embodiment of the present invention, which are cross-sectional views corresponding to the steps shown in FIG. 3A and FIG. 3B;

FIG. 11A and FIG. 11B are views showing the case of forming the plasma oxide film in the method of manufacturing the semiconductor device according to the embodiment of the present invention, which are cross-sectional views corresponding to the steps shown in FIG. 4A and FIG. 4B;

FIG. 12 is a schematic view showing a schematic structure of a plasma processing apparatus having a radial line slot antenna which can be used in the embodiment of the present invention;

FIG. 13A and FIG. 13B are cross-sectional views showing a conventional method of manufacturing a semiconductor device employing an STI method as an element isolating method;

FIG. 14A and FIG. 14B are views showing the conventional method of manufacturing the semiconductor device, which are cross-sectional views showing steps subsequent to those shown in FIG. 13A and FIG. 13B;

FIG. 15A and FIG. 15B are views showing the conventional method of manufacturing the semiconductor device, which are cross-sectional views showing steps subsequent to those shown in FIG. 14A and FIG. 14B;

FIG. 16A and FIG. 16B are views showing the conventional method of manufacturing the semiconductor device, which are cross-sectional views showing steps subsequent to those shown in FIG. 15A and FIG. 15B;

FIG. 17A and FIG. 17B are views showing the conventional method of manufacturing the semiconductor device, which are cross-sectional views showing steps subsequent to those shown in FIG. 16A and FIG. 16B;

FIG. 18 is a cross-sectional view showing outward diffusion in the conventional method of manufacturing the semiconductor device;

FIG. 19A and FIG. 19B are cross-sectional views showing a conventional method of manufacturing a semiconductor device employing plasma oxidization; and

FIG. 20 is a cross-sectional view showing a state of a silicon substrate in the case of employing the plasma oxidization.

### DETAILED DESCRIPTION OF THE PREFERRED EMBODIMENTS

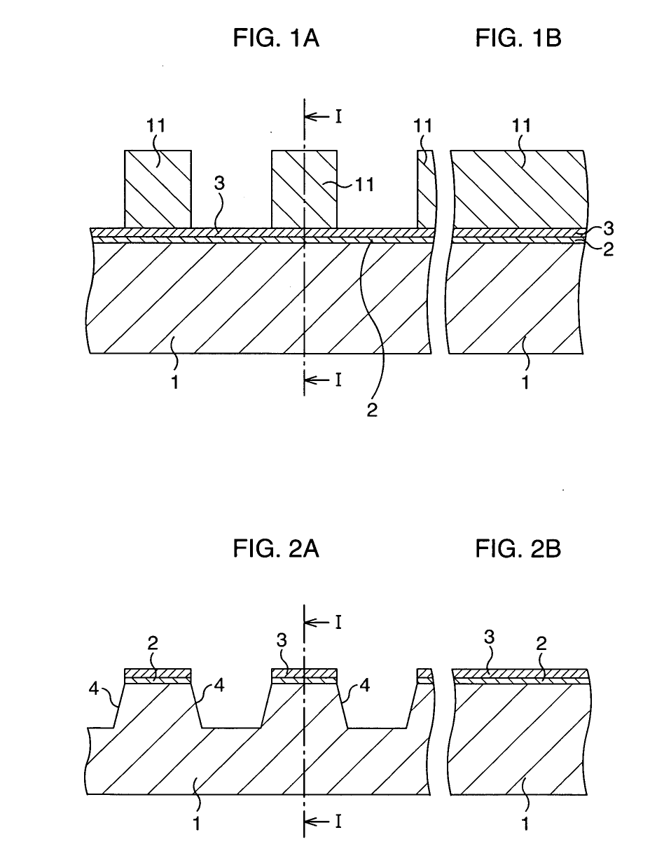

Hereinafter, a semiconductor device and a method of manufacturing the same according to an embodiment of the present invention will be described specifically with reference to the attached drawings. Here, for the sake of convenience, the structure of the semiconductor device will be described together with a forming method thereof. FIG. 1 to FIG. 6 are cross-sectional views showing the method of manufacturing the semiconductor device according to the embodiment of the present invention in order of steps. A cross section take along the I-I line in each view A in FIG. 1 to FIG. 6 corresponds to each view B.

In this embodiment, first, as shown in FIG. 1A, FIG. 1B, an oxide film 2 is formed on a surface of a semiconductor substrate 1 such as a silicon substrate with a film thickness of approximately 1 nm to 80 nm, and a SiN film 3 is formed thereon with a film thickness of approximately 50 nm to 250 nm. In the semiconductor substrate 1, an impurity such as boron is introduced in advance. Next, a resist film is formed on the SiN film 3, and this resist film is patterned in a shape having openings at portions where element isolation regions are to be formed, thereby forming a resist pattern 11. Note that when boron is introduced in the semiconductor substrate 1, the semiconductor substrate 1 becomes a p-type semiconductor substrate, but an n-type impurity may be introduced therein in advance so that the semiconductor substrate 1 becomes an n-type semiconductor substrate.

Next, as shown in FIG. 2A and FIG. 2B, with the resist pattern 11 being a mask, the SiN film 3, the oxide film 2 and the semiconductor substrate 1 are etched. As a result, trenches 4 each having a depth of approximately 100 nm to 600 nm are formed in the semiconductor substrate 1. Then, the resist pattern 11 is removed.

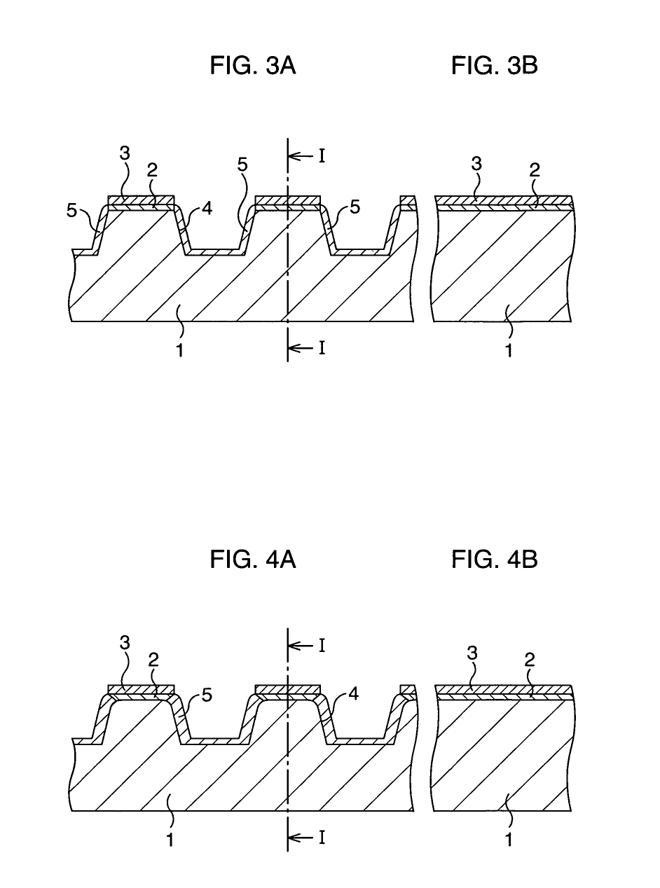

Thereafter, plasma oxynitride films 5 are formed on side wall surfaces and bottom surfaces of the trenches 4 with a film thickness of approximately 0.5 nm to 30 nm at a processing temperature of approximately 300° C. to 650° C, as shown in FIG. 3A, FIG. 3B. In an oxidizing method using an ordinary thermal processing, the semiconductor substrate is inserted in a processing apparatus at a temperature of approximately 650° C. However, in order to reduce the outward diffusion of impurities from the semiconductor substrate than in the thermal processing, it is preferable to form the plasma oxynitride films at or below that temperature. When forming the plasma oxynitride films 5, radicals O* and N* are generated, or radicals O* and NH* are generated in a plasma atmosphere of a gas including N₂O or O₂ and N₂ or NH₃ for example. Additionally, in a gas used when growing the plasma oxynitride films 5, a rare gas such as Kr or Ar for example may be included, and also H₂ may be included.

After the plasma oxynitride films 5 are formed, a thermally oxidized film having a film thickness of approximately 5 nm to 100 nm is formed under the plasma oxynitride films 5 at a temperature of approximately 900° C. to 1100° C. As a result of this thermal oxidization, the plasma oxynitride films 5 become thick, and accompanying this, corner portions where the outermost surface of the semiconductor substrate 1 meets the wall surfaces of the trenches 4 are rounded, as shown in FIG. 4A and FIG. 4B. The reason why the thermal oxidization processing is preferred to be performed at a temperature of approximately 900° C. or higher is to round these corner portions. At this time, being different from a conventional step of forming a thermally oxidized film 105, the side wall surfaces and the bottom surfaces of the trenches 4 are covered by the plasma oxynitride films 5, so that the outward diffusion of impurities such as boron does not occur even when the thermal oxidization processing is performed at a high temperature.

When the film thickness of the thermally oxidized film is too large as compared with a channel length, the roundness of the corner portions becomes larger and the channel length becomes substantially longer, and when it is too small as compared with the channel length, the corner portions cannot be rounded. Accordingly, it is preferable that the film thickness of the thermally oxidized film is approximately 1% to 20% of the channel length. Further, when the film thickness of the plasma oxynitride films 5 is too large as compared with the film thickness of the thermally oxidized film, the corner portions will not be rounded adequately during thermal oxidization, and when it is too small as compared with the film thickness of the thermally oxidized film, the outward diffusion from the semiconductor device cannot be suppressed enough. Thus, it is preferred that the film thickness of the plasma oxynitride films 5 is approximately 10% to 30% of the film thickness of the thermally oxidized film.

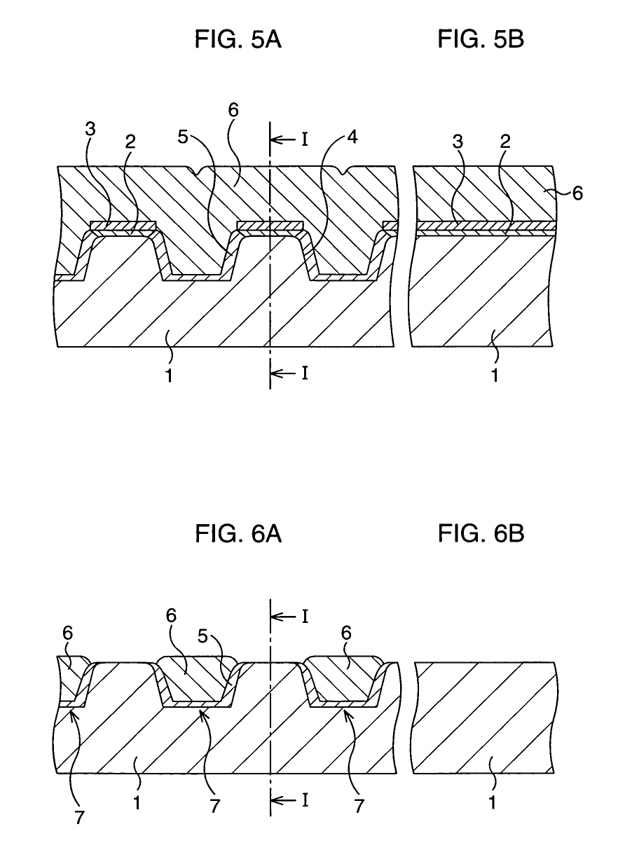

Subsequently, as shown in FIG. 5A and FIG. 5B, a silicon oxide film 6 is formed on the entire surface by a CVD method for example, and the trenches 4 are completely filled with the silicon oxide film 6.

Next, until the SiN films 3 become exposed, planarization etching of the silicon oxide film 6 is performed by a CMP method. Then, as shown in FIG. 6A and FIG. 6B, the SiN films 3 remaining on regions other than the regions where the element isolation regions are to be formed are removed using a phosphoric acid or the like. By these steps, element isolation regions 7 are formed.

Thereafter, elements such as transistors are formed inside element regions sectioned by the element isolation regions 7, and furthermore, an interlayer insulation film, a wiring, and so on are formed above them, thereby completing the semiconductor device.

By the method of manufacturing the semiconductor device according to this embodiment as described above, the plasma oxynitride films 5 are formed instead of the conventional thermally oxidized film, so that the outward diffusion of impurities from the semiconductor substrate 1 does not occur when the insulation films are formed. Therefore, any problems such as formation of a parasitic transistor hardly occur even when ions of impurities are not implanted thereafter.

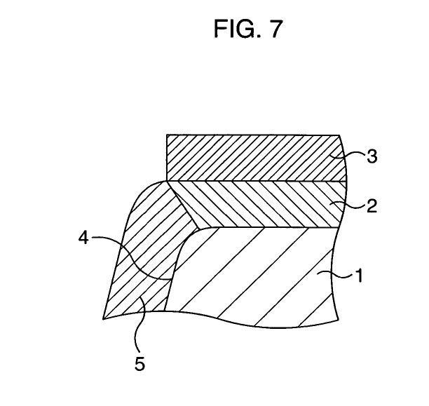

Further, when merely the plasma oxynitride films 5 are formed, reliability becomes low due to the formation of a parasitic transistor similarly to a conventional method of forming a plasma oxide film. However, in this embodiment, after the plasma oxynitride films 5 are formed, the thermal oxidization film is formed under the plasma oxynitride films 5, so that the portions where the outermost surface of the semiconductor substrate 1 meets the wall surfaces of the trenches 4 are turned into a curved surface respectively. As a result, as shown in FIG. 7, the outermost surface of the semiconductor substrate 1 and the wall surfaces of the trenches 4 meet each other while forming a curved surface respectively, and hence a parasitic transistor is hardly formed at these portions.

Here, in the above-described embodiment, the plasma oxynitride films 5 are formed on the side wall surfaces and the bottom surfaces of the trenches 4, but plasma oxide films or plasma nitride films may be formed instead of the plasma oxynitride films 5, and thereafter the thermally oxidized film may be formed under the plasma oxide films or the plasma nitride films.

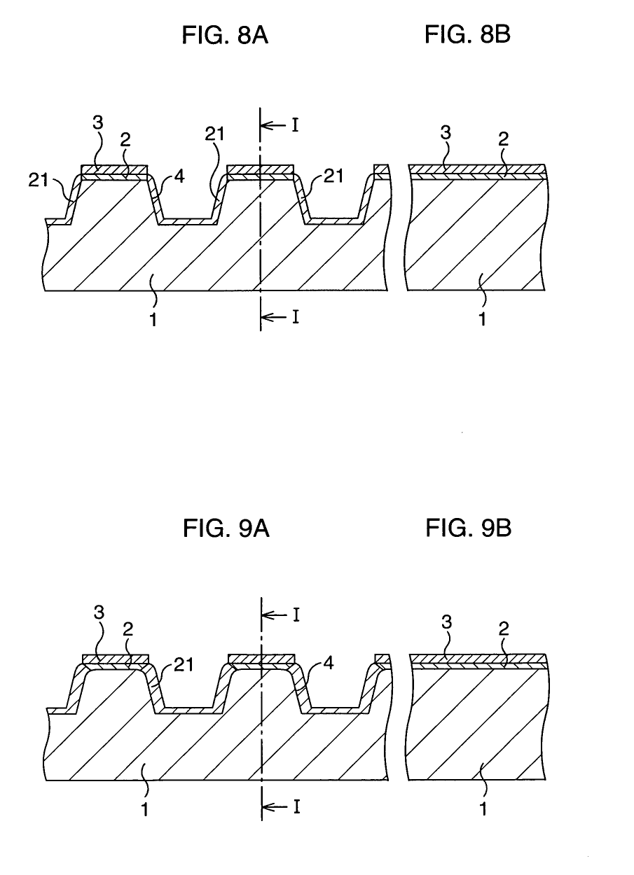

When forming the plasma nitride films instead of the plasma oxynitride films 5, plasma nitride films 21 are formed on the side wall surfaces and the bottom surfaces of the trenches 4 with a film thickness of approximately 0.5 nm to 30 nm at a processing temperature of approximately 300° C. to 650° C, as shown in FIG. 8A, FIG. 8B (corresponding to FIG. 3A, FIG. 3B). In the oxidizing method using an ordinary thermal processing, the semiconductor substrate is inserted in a processing apparatus at a temperature of approximately 650° C. However, in order to reduce the outward diffusion of impurities from the semiconductor substrate than in the thermal processing, it is preferable to form the plasma nitride films at or below that temperature. When forming the plasma nitride films 21, radicals N* or NH* are generated in a plasma atmosphere of a gas including N₂ or NH₃ for example. Additionally, in a gas used when growing the plasma nitride films 21, a rare gas such as Kr or Ar for example may be included, and also H₂ may be included.

After the plasma nitride films 21 are formed, a thermally oxidized film having a film thickness of approximately 5 nm to 100 nm is formed under the plasma nitride films 21 at a temperature of approximately 900° C. to 1100° C. As a result of this thermal oxidization, the plasma nitride films 21 become thick, and accompanying this, corner portions where the outermost surface of the semiconductor substrate 1 meets the wall surfaces of the trenches 4 are rounded, as shown in FIG. 9A and FIG. 9B (corresponding to FIG. 4A and FIG. 4B). The reason why the thermal oxidization processing is preferred to be performed at a temperature of approximately 900° C. or higher is to round these corner portions. At this time, being different from the conventional step of forming the thermally oxidized film 105, the side wall surfaces and the bottom surfaces of the trenches 4 are covered by the plasma nitride films 21, so that the outward diffusion of impurities such as boron does not occur even when the thermal oxidization processing is performed at a high temperature.

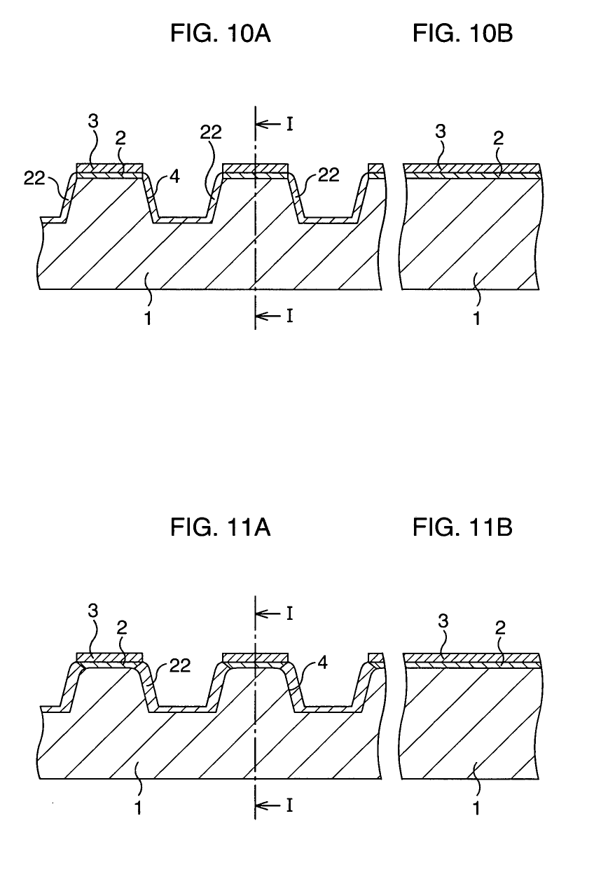

Further, when forming the plasma oxide films instead of the plasma oxynitride films 5, plasma oxide films 22 are formed on the side wall surfaces and the bottom surfaces of the trenches 4 with a film thickness of approximately 0.5 nm to 30 nm at a processing temperature of approximately 300° C. to 650° C., as shown in FIG. 10A, FIG. 10B (corresponding to FIG. 3A, FIG. 3B). In the oxidizing method using an ordinary thermal processing, the semiconductor substrate is inserted in a processing apparatus at a temperature of approximately 650° C. However, in order to reduce the outward diffusion of impurities from the semiconductor substrate than in the thermal processing, it is preferable to form the plasma oxide films at or below that temperature. When forming the plasma oxide films 22, radicals O* are generated in a plasma atmosphere of a gas including O₂ for example. Additionally, in a gas used when growing the plasma oxide films 22, a rare gas such as Kr or Ar for example may be included, and also H₂ may be included.

After the plasma oxide films 22 are formed, a thermally oxidized film having a film thickness of approximately 5 nm to 100 nm is formed under the plasma oxide films 22 at a temperature of approximately 900° C. to 1100° C. As a result of this thermal oxidization, the plasma oxide films 22 become thick, and accompanying this, corner portions where the outermost surface of the semiconductor substrate 1 meets the wall surfaces of the trenches 4 are rounded, as shown in FIG. 11A and FIG. 11B (corresponding to FIG. 4A and FIG. 4B). The reason why the thermal oxidization processing is preferred to be performed at a temperature of approximately 900° C. or higher is to round these corner portions. At this time, being different from the conventional step of forming the thermally oxidized film 105, the side wall surfaces and the bottom surfaces of the trenches 4 are covered by the plasma oxide films 22, so that the outward diffusion of impurities such as boron does not occur even when the thermal oxidization processing is performed at a high temperature.

As described above, even in the case of forming the plasma nitride films 21 or the plasma oxide films 22 instead of the plasma oxynitride films 5, the outward diffusion of impurities from the semiconductor substrate 1 is prevented, and also the top ends of the wall surfaces of the trenches are rounded. Therefore, a parasitic transistor is hardly formed, and thus high reliability can be achieved.

Further, the method of forming the plasma oxynitride film, the plasma nitride film or the plasma oxide film and a plasma processing apparatus used for the formation thereof are not particularly limited, but it is preferred to use an apparatus described below to form the plasma oxynitride film, the plasma nitride film or the plasma oxide film.

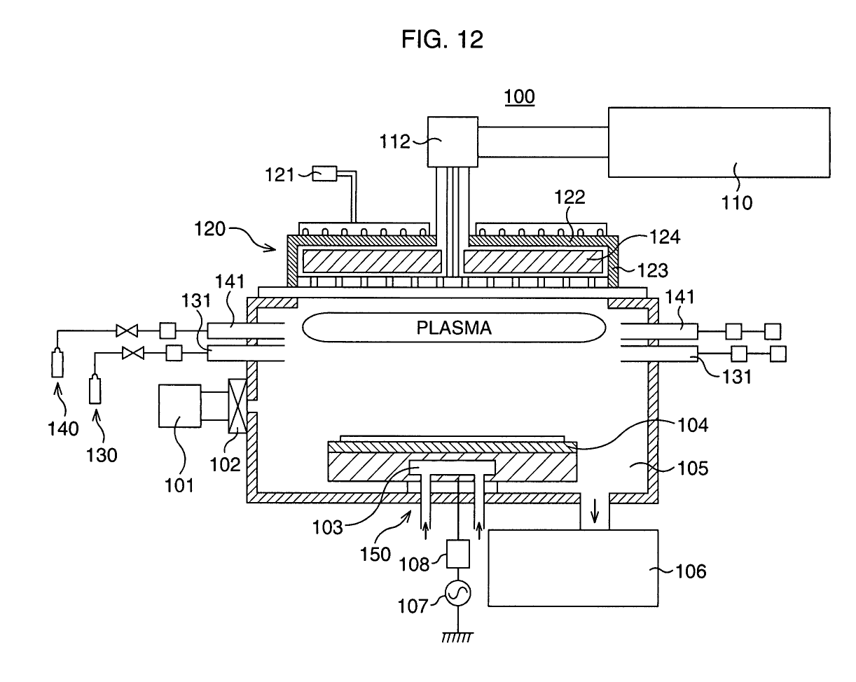

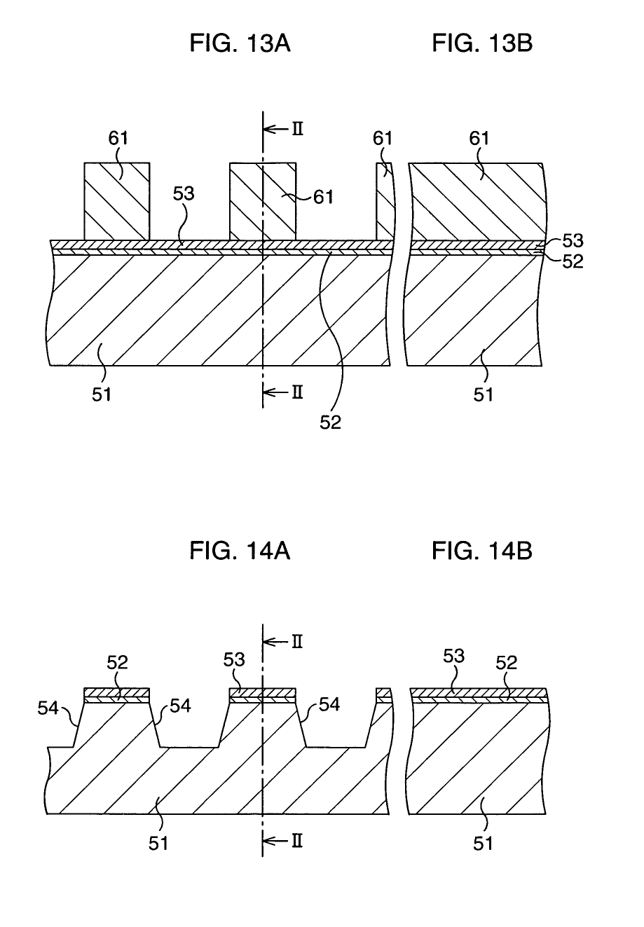

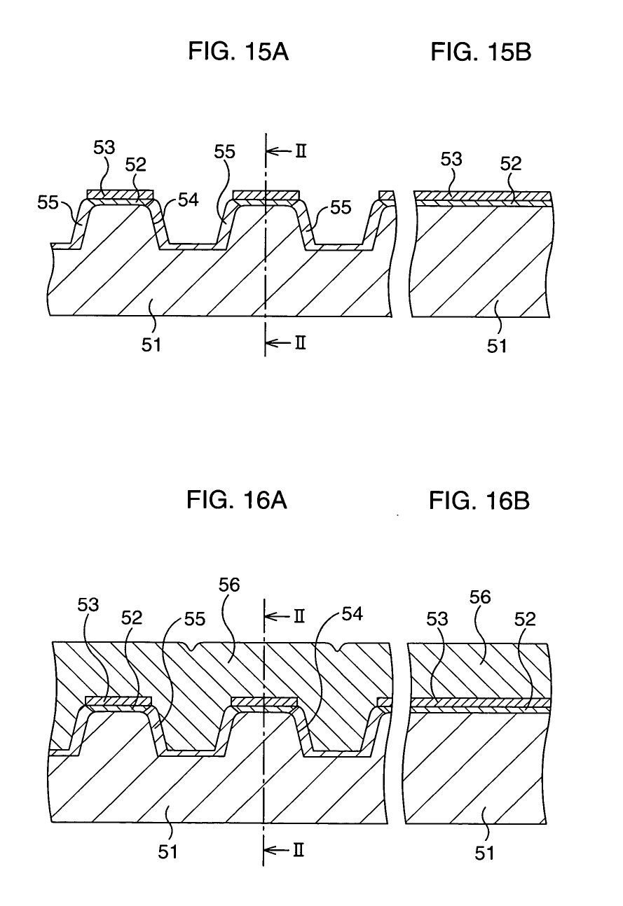

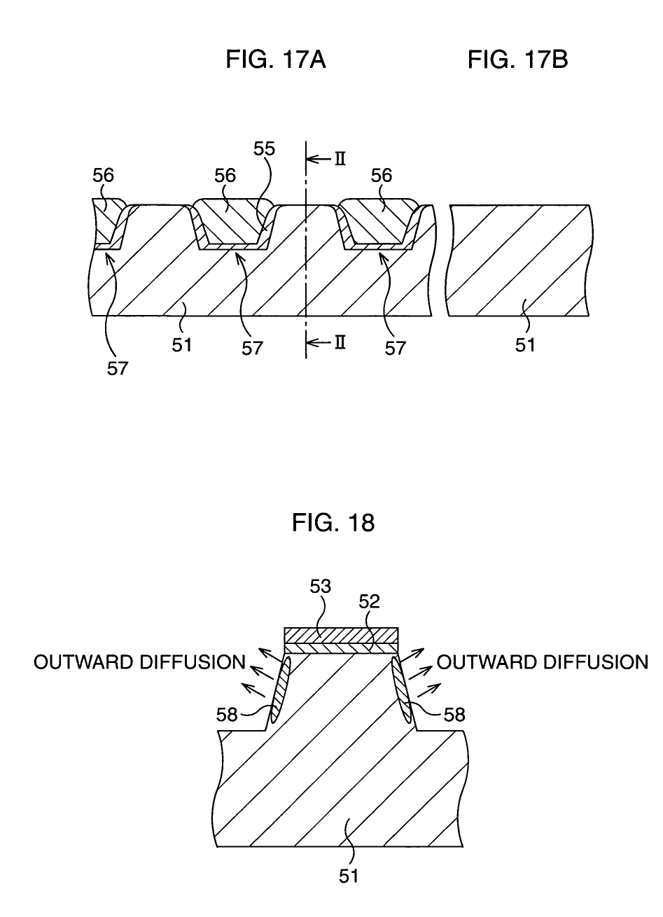

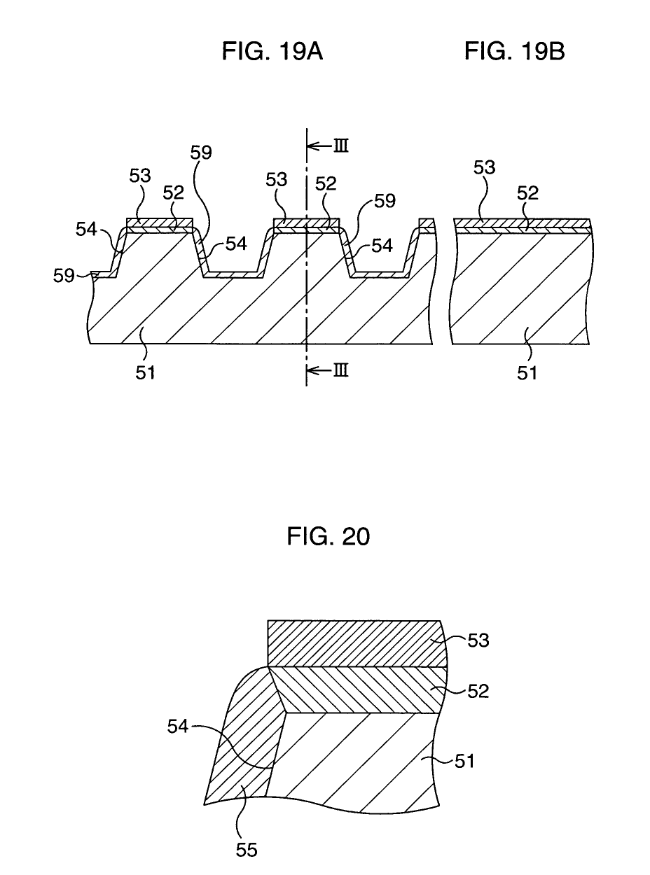

Specifically, a plasma processing apparatus having a radial line slot antenna as shown in FIG. 12 is used to form the plasma oxynitride film or the plasma nitride film. This plasma processing apparatus 100 has a structure including a gate bulb 102 communicative to a cluster tool 101, a processing chamber 105 capable of accommodating a susceptor 104 on which an object W to be processed (the semiconductor substrate 1 in this embodiment) is mounted having a cooling jacket 103 for cooling the object W to be processed during the plasma processing, a high vacuum pump 106 connected to the processing chamber 105, a microwave source 110, an antenna member 120, a bias high frequency power source 107 and a matching box 108 which constitute an ion plating together with the antenna member 120, gas supply systems 130, 140 having gas supply rings 131, 141, and a temperature control unit 150 performing temperature control of the object W to be processed.

The microwave source 110 is constituted of a magnetron for example, and is normally capable of generating a microwave of 2.45 GHz (5 kW for example). Thereafter, the transmission mode of the microwave is converted into a TM, a TE or a TEM mode by a mode converter 112.

The antenna member 120 has a temperature adjusting plate 122, an accommodating member 123, and a dielectric plate 230. The temperature adjusting plate 122 is connected to a temperature control device 121, and the accommodating member 123 accommodates a wavelength shortening material 124 and a slot electrode (not shown) in contact with the wavelength shortening material 124. This slot electrode is referred to as a radial line slot antenna (RLSA) or an ultrahigh efficiency flat antenna. However, another type of antenna, for example a single layer waveguide flat antenna, a dielectric substrate parallel plate slot array, or the like may be applied.

Using the plasma processing apparatus having the above-described structure, film formation is carried out with a temperature condition of approximately 300° C. to 650° C.

When such a plasma processing apparatus having a radial line slot antenna is used to perform film formation, the ion radiation energy of plasma is preferred to be 7 eV or lower, and the potential energy of plasma is preferred to be 10 eV or lower.

Then, formation of the plasma oxynitride film, the plasma nitride film, the plasma oxide film or the like can be performed using the above-described plasma processing apparatus by a sequence of film forming methods including a plasma oxidizing method and a plasma nitriding method or at least one of the plasma oxidizing method and the plasma nitriding method.

### INDUSTRIAL APPLICABILITY

According to the present invention, a plasma oxide film, a plasma nitride film, or a plasma oxynitride film is formed on side wall surfaces of a trench for element isolation, so that outward diffusion of impurities from a semiconductor substrate can be prevented during this formation. Further, an upper end portion of the trench is turned into a curved surface, so that a parasitic transistor is hardly formed at this portion. Therefore, excellent characteristics can be achieved.

1. A semiconductor device, comprising:
a semiconductor substrate having a surface in which a trench for element isolation is formed;
one kind of insulation film selected from the group consisting of a plasma oxide film, a plasma nitride film, and a plasma oxynitride film and is formed at least on a side wall surface of the trench; and
an insulation film for element isolation, said insulation film being embedded in the trench,
wherein a topmost portion of the side wall surface of the trench of said semiconductor substrate is turned into a gently curved surface.

2. The semiconductor device according to claim 1,
wherein an impurity is introduced into said semiconductor substrate.

3. A method of manufacturing a semiconductor device, comprising the steps of:
forming a trench for element isolation in a surface of a semiconductor substrate;
forming an insulation film at least on a side wall surface of the trench by a sequence of film forming methods including a plasma oxidizing method and a plasma nitriding method or at least one of the plasma oxidizing method and the plasma nitriding method; and
thermally oxidizing the semiconductor substrate to thereby turn a topmost portion of the side wall surface of the trench of the semiconductor substrate into a gently curved surface.

4. The method of manufacturing the semiconductor device according to claim 3, further comprising:
a step of introducing an impurity into the semiconductor substrate before said step of forming the insulation film.

5. The method of manufacturing the semiconductor device according to claim 3,
wherein said step of forming the insulation film is performed in an atmosphere of plasma of a source gas which includes at least one kind of molecule selected from the group consisting of an oxygen molecule, a nitrogen molecule and an ammonia molecule.

6. The method of manufacturing the semiconductor device according to claim 5,
wherein the source gas further includes at least one kind of molecule selected from the group consisting of an oxygen molecule and a nitrogen monoxide molecule in addition to at least one kind of molecule selected from the group consisting of a nitrogen molecule and an ammonia molecule.

7. The method of manufacturing the semiconductor device according to claim 5,
wherein said step of forming the insulation film includes a step of generating in the atmosphere at least one kind of radical selected from the group consisting of an oxygen radical, a nitrogen radical, and an ammonia radical.

8. The method of manufacturing the semiconductor device according to claim 7,
wherein said step of forming the insulation film includes a step of further generating in the atmosphere an oxygen radical in addition to at least one kind of radical selected from the group consisting of a nitrogen radical and an ammonia radical.

9. The method of manufacturing the semiconductor device according to claim 5,
wherein the source gas further includes a rare gas.

10. The method of manufacturing the semiconductor device according to claim 9,
wherein the rare gas includes at least one kind of molecule selected from the group consisting of a krypton molecule and an argon molecule.

11. The method of manufacturing the semiconductor device according to claim 5,
wherein the source gas further includes a hydrogen molecule.

12. The method of manufacturing the semiconductor device according to claim 5,
wherein in said step of forming the insulation film, ion radiation energy of the plasma is 7 eV or lower.

13. The method of manufacturing the semiconductor device according to claim 5,
wherein in said step of forming the insulation film, potential energy of the plasma is 10 eV or lower.

14. The method of manufacturing the semiconductor device according to claim 5,
wherein in said step of forming the insulation film, a microwave radiated from a flat antenna in which a plurality of slits are formed is used to excite the source gas to thereby generate the plasma.

15. The method of manufacturing the semiconductor device according to claim 14,
wherein a radial line slot antenna is used as the flat antenna.

16. The method of manufacturing the semiconductor device according to claim 3,
wherein said step of thermally oxidizing the semiconductor substrate is performed in a temperature range of 900° C. to 1100° C.

17. The method of manufacturing the semiconductor device according to claim 3,
wherein said step of forming the insulation film is performed in a temperature range of 300° C. to 650° C.
